(19) United States
(12) Patent Application Publication
(10) Pub. No.: US 2009/0173373 A1
(43) Pub. Date: Jul. 9, 2009

(54) Group III-Nitride Solar Cell with Graded Compositions

(76) Inventors: Wladyslaw Walukiewicz, Kensington, CA (US); Joel W. Ager, III, Berkeley, CA (US); Kin Man Yu, Lafayette, CA (US)

Correspondence Address: GREENBERG TRAURIG LLP (LA), 2450 COLORADO AVENUE, SUITE 400E, INTELLECTUAL PROPERTY DEPARTMENT, SANTA MONICA, CA, 90404, US

(21) Appl. No.: 12/348,127

(22) Filed: Jan. 2, 2009

Related U.S. Application Data
(60) Provisional application No. 61/019,536, filed on Jan. 7, 2008.

(51) Int. Cl. H01L 31/042; H01L 31/00

(52) U.S. Cl. 136/244; 136/256

(57) ABSTRACT

A compositionally graded Group III-nitride alloy is provided for use in a solar cell. In one or more embodiment, an alloy of either InGaN or InAlN formed in which the In composition is graded between two areas of the alloy. The compositionally graded Group III-nitride alloy can be utilized in a variety of types of solar cell configurations, including a single P-N junction solar cell having tandem solar cell characteristics, a multijunction tandem solar cell, a tandem solar cell having a low resistance tunnel junction and other solar cell configurations. The compositionally graded Group III-nitride alloy possesses direct band gaps having a very large tuning range, for example extending from about 0.7 to 3.4 eV for InGaN and from about 0.7 to 6.2 eV for InAlN.

### CROSS REFERENCE TO RELATED APPLICATION(S)

This application claims priority to U.S. Provisional Patent Application Ser. No. 61/019,536, entitled “Group III-Nitride Solar Cell with Graded Compositions,” filed on Jan. 7, 2008, the contents of which are incorporated herein by reference.

### STATEMENT OF GOVERNMENTAL INTEREST

The invention described and claimed herein was made in part utilizing funds supplied by the U.S. Department of Energy under Contract No. DE-AC02-05CH11231. The government has certain rights in this invention.

### BACKGROUND OF THE INVENTION

1. Field of the Invention

The disclosure relates to solar cells and, more particularly, to a compositional grading of Group III-nitride alloys in solar cells for improved solar cell performance.

2. Background Discussion

Solar or photovoltaic cells are semiconductor devices having P-N junctions which directly convert radiant energy of sunlight into electrical energy. Conversion of sunlight into electrical energy involves three major processes: absorption of sunlight into the semiconductor material; generation and separation of positive and negative charges creating a voltage in the solar cell; and collection and transfer of the electrical charges through terminals connected to the semiconductor material. A single depletion region for charge separation typically exists in the P-N junction of each solar cell.

Current traditional solar cells based on single semiconductor material have an intrinsic efficiency limit of approximately 31%. A primary reason for this limit is that no one material has been found that can perfectly match the broad ranges of solar radiation, which has a usable energy in the photon range of approximately 0.4 to 4 eV. Light with energy below the bandgap of the semiconductor will not be absorbed and converted to electrical power. Light with energy above the bandgap will be absorbed, but electron-hole pairs that are created quickly lose their excess energy above the bandgap in the form of heat. Thus, this energy is not available for conversion to electrical power.

Higher efficiencies have been attempted to be achieved by using stacks of solar cells with different band gaps, thereby forming a series of solar cells, referred to as “multijunction,” “cascade,” or “tandem” solar cells. Tandem solar cells are the most efficient solar cells currently available. Tandem cells are made by connecting a plurality (e.g., two, three, four, etc.) P-N junction solar cells in series. Tandem cells are typically formed using higher gap materials in the top cell to convert higher energy photons, while allowing lower energy photons to pass down to lower gap materials in the stack of solar cells. The bandgaps of the solar cells in the stack are chosen to maximize the efficiency of solar energy conversion, where tunnel junctions are used to series-connect the cells such that the voltages of the cells sum together. Such multijunction solar cells require numerous layers of materials to be formed in a stacked arrangement.

### SUMMARY

In accordance with one or more embodiments, a compositionally graded Group III-nitride alloy is provided for use in a solar cell. In one or more embodiment, an alloy of either InGaN or InAlN is formed in which the Indium (In) composition is graded between two areas of the alloy. In one or more embodiments, the compositionally graded Group III-nitride alloy possesses direct band gaps having a very large tuning range, for example extending from about 0.7 to 3.4 eV for InGaN and from about 0.7 to 6.2 eV for InAlN.

In accordance with one or more embodiments, a single P-N junction solar cell is provided having multiple regions for charge separation while allowing the electrons and holes to recombine such that the voltages associated with both depletion regions of the solar cell will add together. In one or more embodiments, the conduction band edge (CBE) of a top layer in the solar cell is formed to line up with the valence band edge (VBE) of a lower layer in the solar cell. In accordance with one or more embodiments, a single P-N junction solar cell is provided having a compositionally graded Group III-nitride alloy of either InGaN or InAlN formed on one side of the P-N junction with Si formed on the other side in order to produce characteristics of a tandem solar cell with its two energy gaps through the formation of only a single P-N junction.

In accordance with one or more embodiments, a multijunction tandem solar cell is provided in which one of the solar cells includes a compositionally graded Group III-nitride alloy. In accordance with one or more embodiments, a tandem solar cell is provided having a low-resistance tunnel junction formed between two solar cells in which one of the solar cells includes a compositionally graded Group III-nitride alloy.

In accordance with one or more of the embodiments described herein, the Group III-nitride alloy utilized in the single P-N junction solar cell is either an InₓGa₁₋ₓN alloy or an InₓAl₁₋ₓN alloy in which the Indium (In) composition can be graded over a wide range (e.g., anywhere between x=0.0 to x=1.0) between two surfaces of a layer of the alloy in order to provide a wide range of direct gap grading. Solar cells formed in accordance with one or more embodiments using a compositionally graded Group III-nitride alloy will allow higher power conversion efficiencies to be achieved.

In accordance with one or more embodiments, a solar cell is provided having a compositionally graded alloy of either InGaN or InAlN formed on one side of the P-N junction with Si formed on the other side, wherein an additional n+ layer is formed between the Si layer and a contact to produce a back surface field (BSF).

### DRAWINGS

The above-mentioned features and objects of the present disclosure will become more apparent with reference to the following description taken in conjunction with the accompanying drawings wherein like reference numerals denote like elements and in which:

FIG. 1 is a block diagram representation of a single P-N junction tandem solar cell in accordance with one or more embodiments of the present disclosure.

FIG. 2 is a more detailed perspective view of FIG. 1 showing the various regions in a single P-N junction tandem solar cell in accordance with one or more embodiments of the present disclosure.

FIG. 3 is a block diagram representation of a single P-N junction tandem solar cell having a compositionally graded Group III-nitride layer in accordance with one or more embodiments of the present disclosure.

FIG. 4 is a graphical illustration of the calculated band diagram for the heterojunction of a single P-N junction tandem solar cell having a compositionally graded Group III-nitride layer in accordance with one or more embodiments of the present disclosure.

FIG. 5 is a block diagram representation of a single P-N junction tandem solar cell having a compositionally graded layer and a back surface field in accordance with one or more embodiments of the present disclosure.

FIG. 6 is a graphical illustration of the calculated band diagram for the heterojunction of a single P-N junction tandem solar cell in accordance with one or more embodiments of the present disclosure.

FIG. 7 is a graphical illustration of the calculated band diagram of a single P-N junction tandem solar cell having a compositionally graded Group III-nitride layer on both sides of the P-N junction in accordance with one or more embodiments of the present disclosure.

FIG. 8 is a block diagram representation of a multijunction tandem solar cell having a compositionally graded Group III-nitride layer and a back surface field in accordance with one or more embodiments of the present disclosure.

FIGS. 9A and 9B are graphical illustrations of the calculated band diagrams for specific embodiments of the multijunction tandem solar cell having a compositionally graded Group III-nitride layer of FIG. 7.

FIGS. 10A and 10B are graphical illustrations of the calculated band diagrams for specific embodiments of a tandem solar cell having a compositionally graded Group III-nitride layer and a low-resistance tunnel junction in accordance with the present disclosure.

### DETAILED DESCRIPTION

In general, the present disclosure is directed to a photovoltaic device or solar cell including a compositionally graded Group III-nitride alloy. Certain embodiments of the present disclosure will now be discussed with reference to the aforementioned figures, wherein like reference numerals refer to like components.

Referring now to FIG. 1, a block diagram illustration of a single P-N junction tandem solar cell 100 is shown generally in accordance with one or more embodiments. One of the layers 102 and 104 is formed as a p-type material while the other of the layers 102 and 104 is formed as an n-type material, such that a single P-N junction 105 exists between the layers 102 and 104. Each of the layers 102 and 104 can also be described and/or formed as its own subcell within the solar cell 100. In one or more embodiments, the conduction band edge (CBE) of the top layer 102 in the solar cell is formed to line up with the valence band edge (VBE) of the lower layer 104 in the solar cell 100. In one or more embodiments, the solar cell 100 includes a layer 102 of a compositionally graded Group III-nitride alloy and a Si layer 104. Electrical contacts 106 and 108 are formed, respectively, on the top of or otherwise coupled to the Group III-nitride alloy layer 102 and on the bottom of or otherwise coupled to the Si layer 104. In one or more embodiments, the top electrical contact 106 should be formed from a substantially transparent conductive material so as to allow solar radiation to travel past the electrical contact 106 to enter into the solar cell 100, such as by forming the contact 106 as Indium-Tin-Oxide or other suitable substantially transparent conductive material or a grid of other metal layers. The electrical contacts 106 and 108 are formed in accordance with methods known to those skilled in the art of manufacturing solar cells.

In one or more embodiments, the Group III-nitride layer 102 is an alloy of In₁₋ₓGaₓN, where 0≦x≦1, having an energy bandgap range of approximately 0.7 eV to 3.4 eV, providing a good match to the solar energy spectrum. In one or more embodiments, the Group III-nitride layer 102 is an alloy of In₁₋ₓAlₓN, where 0≦x≦1, having an energy bandgap range of approximately 0.7 eV to 6.2 eV, also providing a good match to the solar energy spectrum. In one or more embodiments, the Group III-nitride layer 102 is grown by molecular beam epitaxy creating crystals with low electron concentrations and high electron mobilities, while it is understood that other formation methods can further be utilized. For ease of description in the various embodiments described herein, the layer 102 will be referred to as Group III-nitride layer 102, while it is understood that InAlN, InGaN, or another Group III-nitride can interchangeably be substituted in place of one another in the various embodiments described herein.

In one or more embodiments, the Group III-nitride layer 102 is formed as a p-type layer by doping the Group III-nitride layer 102 with a p-type dopant, such as magnesium (Mg), while a thin Si interface layer is counter-doped with a p-type dopant such as Boron (B), Aluminum (Al), Gallium (Ga) or Indium (In). The rest of the Si layer 104 is formed as an n-type layer by doping the Si layer 104 with an n-type dopant, such as phosphorous (P), arsenic (As), germanium (Ge), or antimony (Sb). Typical doping levels for n-type and p-type layers range from 10¹⁵ cm⁻³ to 10¹⁹ cm⁻³. The actual doping levels depend on other characteristics of the layers 102 and 104 of the solar cell 100 and can be adjusted within and outside of this range to maximize the efficiency.

As grown, undoped InGaN films are generally n-type, where in one embodiment the Group III-nitride layer 102 can be doped with Mg acceptors so that the Group III-nitride layer 102 behaves as a p-type. In one specific embodiment, a Mg p-type dopant is used in alloy of In_{y}Ga_{1-y}N where 0.67≦y≦0.95.

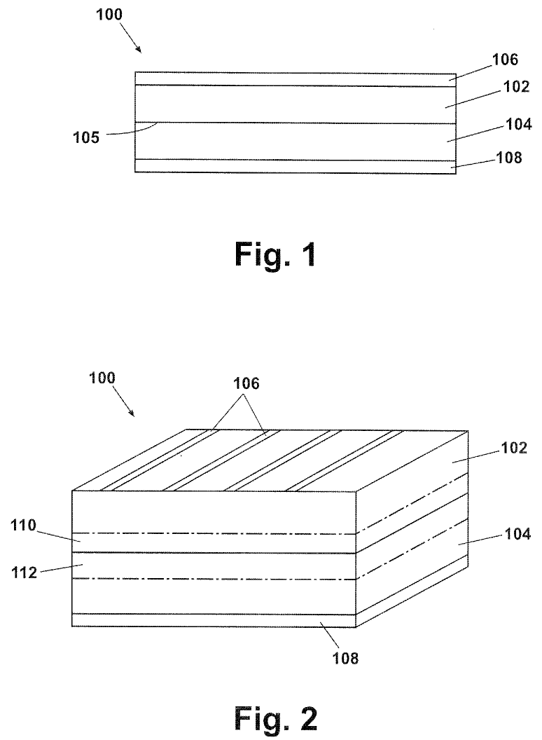

While the P-N junction 105 can be simply formed as represented in FIG. 1 with an Group III-nitride layer 102 positioned against a Si layer 104. In actuality, a plurality of depletion regions will be formed across the P-N junction 105 when the junction 105 is in thermal equilibrium and in a steady state. Electrons and holes will diffuse into regions with lower concentrations of electrons and holes, respectively. Thus, the excess electrons in the n-type Si layer 104 will diffuse into the P-side of the P-N junction 105 while the excess holes in the p-type Group III-nitride layer 102 will diffuse into the N-side of the P-N junction 105. As illustrated in FIG. 2, this will create an Group III-nitride depletion region 110 in the Group III-nitride layer 102 adjacent to the P-N junction 105 and a Si depletion region 112 in the Si layer 104 adjacent to the P-N junction 105.

While the layer 104 is described in many of the embodiments herein as Si layer 104, it is understood that the layer 104 may alternatively comprise a Group III-nitride layer or comprise a layer of another material suitable for photovoltaic devices. In one or more embodiments, the layer 104 may either be compositionally graded or non-graded. It is understood that the various possible compositions for the layer 104 may be interchangeably utilized in the various embodiments described herein as appropriate and depending upon the desired characteristics of the solar cell 100.

In one or more embodiments, the Group III-nitride layer 102 is a compositionally graded Group III-nitride alloy. In one or more embodiment, the Group III-nitride alloy includes either InGaN or InAlN formed in which the Indium (In) composition is graded between two areas of the alloy, wherein the alloy comprises either InₓGa₁₋ₓN or InₓAl₁₋ₓN, where 0≦x≦1.0. By providing a wide range in the compositional grading between two areas of the alloy, InGaN and InAlN alloys provide a very wide range of direct band gap tuning. This advantageous feature is in contrast with other alloys, e.g., AlGaAs, for which the gap is direct for only some part of the alloying range.

When describing that Indium (In) is compositionally graded in the alloy, it is understood that such grading represents a overall or general change in the concentration of Indium (In) from one portion of the alloy to another portion of the alloy, where the rate of change of such Indium (In) concentration may occur linearly, non-linearly, gradually, non-gradually, uniformly or non-uniformly throughout the alloy. It is also understood that the Indium (In) concentration may not vary at all between certain portions of the alloy.

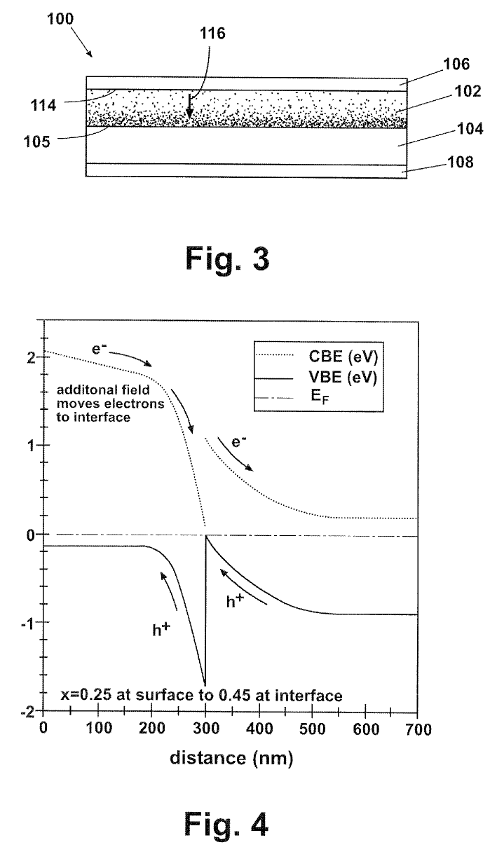

Referring now to FIG. 3, a block diagram illustration of a single P-N junction tandem solar cell 100 is shown generally in accordance with one or more embodiments in which one of layers of the solar cell 100 includes a compositionally graded Group III-nitride alloy as described herein. In one or more embodiments, the Group III-nitride layer 102 is an InₓGa₁₋ₓN alloy in which the Indium (In) composition is graded from a lower Indium (In) concentration at the surface 114 of the Group III-nitride layer 102 to a higher Indium (In) concentration at the interface or junction 105 with the Si layer 104. In one or more embodiments, the Group III-nitride layer 102 is an InₓAl₁₋ₓN alloy in which the Indium (In) composition is graded from a lower Indium (In) concentration at the surface 114 of the Group III-nitride layer 102 to a higher Indium (In) concentration at the interface or junction 105 with the Si layer 104. In each of the embodiments, the concentration of Indium (In) within the Group III-nitride layer 102 generally increases in the direction of directional arrow 116, where the variable shading shown in the Group III-nitride layer 102 in FIG. 3 illustrates the increasing concentration of Indium (In) within the layer 102 in the areas closest to the junction 105 with the Si layer 104.

By compositionally grading the Indium (In) in the Group III-nitride layer 102, an additional potential is created that drives electrons toward the junction 105 with the Si layer 104, thereby increasing cell current. Further, the compositional grading of the Group III-nitride layer 102 will provide a larger gap at the surface 114, thereby likely forming a better hole-conducting contact. These advantages associated with the compositional grading will further increase the solar power conversion efficiency of this type of solar cell.

While the Indium (In) concentration can vary between 0≦x≦˜1.0, in one specific embodiment, a film of an InₓGa₁₋ₓN alloy is provided in which the Indium (In) composition is graded from x=0.25 near one side of the film alloy to x=0.45 near the other side of the film alloy. In another specific embodiment, a film of an InₓAl₁₋ₓN alloy is provided in which the Indium (In) composition is graded from x=0.6 near one side of the film alloy to x=0.8 near the other side of the film alloy. The specific ranges specified in these specific embodiments present a good match to the solar spectrum desirable to be absorbed in a solar cell. However, it is understood that InₓGa₁₋ₓN and InₓAl₁₋ₓN provide a wide range of direct band gap tuning, and other values and ranges for InₓGa₁₋ₓN or InₓAl₁₋ₓN, where 0.0≦x≦1.0, can be selected to optimize performance and transport.

For one embodiment having an n-type Si layer 104 and a p-type InₓGa₁₋ₓN layer 102 in which x=0.25 near the surface 114 and x=0.45 near the junction 105, the calculated band diagram showing energy levels in eV vs. distance from the surface 114 in nm is illustrated in FIG. 4. In the illustrated embodiment, the doping is 2×10¹⁷ cm⁻³ in the p-type InₓGa₁₋ₓN layer 102 and 2×10¹⁶ cm⁻³ in the n-type Si layer 104.

When the solar cell 100 is exposed to solar energy, energy transfers from photons in the solar energy to the solar cell 100 when the layers 102 and 104 absorb lightwaves that contain the same amount of energy as their bandgap. A bandgap is the energy required to push an electron from a material's valence band to its conduction band. Based upon an experimental measurement of a 1.05±0.25 eV valence band offset between InN and GaN and the known electron affinity of GaN, InN is predicted to have an electron affinity of 5.8 eV, the largest of any known semiconductor. Forming the layer 102 as an alloy of InGaN or InAlN allows a wide bandgap tuning range, 0.7 to 3.4 eV for InGaN and 0.7 to 6.0 eV for InAlN.

By aligning the conduction band of one of the layers 102 or 104 with the valence band of the other one of the layers 102 or 104, a low resistance tunnel junction is produced between the layers 102 and 104. The electron affinity (energy position of the conduction band minimum (CBM) with respect to the vacuum level) can also be tuned over a wide range, 5.8 eV to 2.1 eV in InAlN and 5.8 eV to 4.2 eV in InGaN. In one embodiment, for the composition of approximately Al_{0.3}In_{0.7}N or In_{0.45}Ga_{0.55}N, the conduction band of AlInN/InGaN can be made to align with the valence band of Si, creating the conditions for a very low resistance tunnel between the layers 102 and 104 without the requirement of additional heavily doped layers as typically required in previous multijunction solar cells, which greatly simplifies the design of the single junction tandem solar cell 100 embodiment over multi-junction solar cells.

The solar cell 100 having a single P-N junction 105 between the p-type Group III-nitride layer 102 (InGaN or InAlN) and the n-type Si layer 104 provides: (1) two depletion regions for charge separation and (2) a junction 105 that allows electrons and holes to recombine such that the voltages generated from the solar energy in both of the layers 102 and 104 will add together. These types of observations have only previously been attainable in multijunction tandem solar cells with tunnel junction layers and never previously attainable using only a single P-N junction.

The single p-InGaN/n-Si heterojunction of the solar cell 100 behaves in a fundamentally different manner than a usual P-N semiconductor heterojunction. In a normal P-N junction, holes are depleted on the p-type side and electrons are depleted on the n-type side, creating a single depletion region. However, the present p-InGaN/n-Si heterojunction (or p-InAlN/n-Si heterojunction) formed in accordance with one or more embodiments produces two depletion regions. Under illumination, both of these depletion regions can separate charge, such that a single p-InGaN/n-Si or p-InAlN/n-Si heterojunction functions as a two-junction tandem solar cell. Further, at the junction 105 between the layers 102 and 104, there is type inversion (excess electrons on the InGaN side of the junction 105 and excess holes on the Si side of the junction 105), thereby creating the InGaN depletion region 110 and the Si depletion region 112. This type inversion provides a more efficient electron-hole annihilation and series connection of the layers 102 and 104. One representative example of such a single junction tandem solar cell is described in U.S. patent application Ser. No. 11/777,963, filed on Jul. 13, 2007 entitled, “SINGLE P-N JUNCTION TANDEM PHOTOVOLTAIC DEVICE,” the contents of which are incorporated herein by reference.

In one or more embodiments, the dark current (i.e., the output current of the solar cell 100 when no light is acting as an input) can be reduced by heavy counter-doping (i.e., p⁺⁺ in the n-type layer 104 or n⁺⁺ in the p-type layer 102) near the interface between at least one of the layers 102, 104 and the respective one of the electrical contacts 106, 108. This will also increase the open circuit voltage and efficiency of the solar cell 100.

In one or more embodiments, the dark current can be reduced and the open circuit voltage increased through the use of a thin insulating interlayer (e.g., a thin layer of GaN) formed between the layers 102 and 104. The interlayer will serve to increase the barrier for hole leakage from the p-InGaN layer 102 into the n-Si layer 104 while preventing electron leakage from the n-Si layer 104 into the p-InGaN layer 102.

Both of the approaches associated with reducing dark current using heavy counter-doping or a thin insulating layer will increase the barrier against electron and hole leakage by about 0.1 to 0.2 eV compared designs without such features.

In order to form a tandem photovoltaic device using a single P-N junction, the conduction band minimum (CBM) in the upper Group III-nitride layer 102 of the solar cell 100 is formed to be substantially aligned with or lower in energy with respect to the vacuum level than the valence band maximum (VBM) of the lower layer 104 of the solar cell 100. In accordance with one or more embodiments, a solar cell 100 is provided having the efficiency characteristics of a two-junction tandem solar cell with a very simple single P-N junction design. By simply forming a p-InGaN layer 102, which can be thin (<0.5 μm), over a bottom n-Si layer 104, a tandem solar cell 100 can be produced with an efficiency above that of the best currently produced single junction Si solar cells. In one or more embodiments, the Si layer 104 can be formed using polycrystalline, multicrystalline or even amorphous Si. Such a tandem solar cell 100 can be produced with increased efficiency and lower costs compared to previously-known Si technology, which could revolutionize photovoltaics manufacturing.

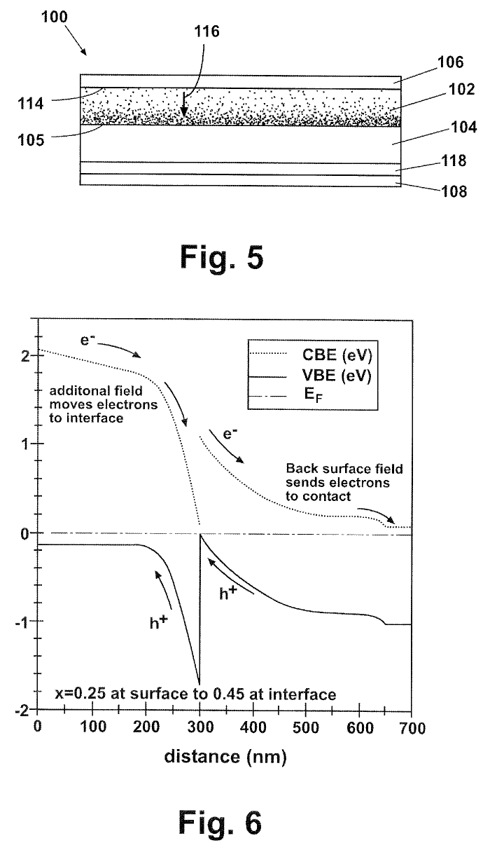

Referring now to FIG. 5, a block diagram illustration of a single P-N junction tandem solar cell 100 is shown generally in accordance with one or more embodiments of the single P-N junction tandem solar cell described herein in which an additional n+ layer 118 is formed between the n-type Si layer 104 and the electrical contact 108 in the compositionally graded solar cell 100 of FIG. 3. The addition of the n+ layer 118 provides a “back surface field” (BSF) which sends electrons to the contact 108 and repels holes. The back surface field is useful in increasing the efficiency of the solar cell 100.

For one embodiment having an n-type Si layer 104 with an additional n+ layer 118 formed thereon and a p-type InₓGa₁₋ₓN layer 102 in which x=0.25 near the surface 114 and x=0.45 near the junction 105, the calculated band diagram showing energy levels in eV vs. distance from the surface 114 in nm is illustrated in FIG. 6. In the illustrated embodiment, the doping is 2×10¹⁷ cm⁻³ in the p-type InₓGa₁₋ₓN layer 102 and 2×10¹⁶ cm⁻³ in the n-type Si layer 104.

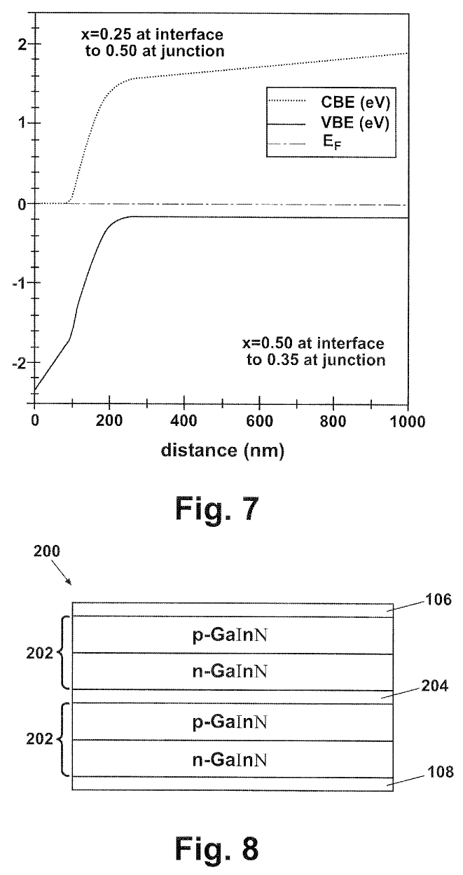

In one or more embodiments, a compositionally-graded Group III-nitride alloy can be formed on both sides of the pn junction. Referring to FIG. 7, a band diagram is illustrated for a simulation of a solar cell having a single np junction in InₓGa₁₋ₓN which has grading on both sides of the junction. For the simulated solar cell, an n-type InₓGa₁₋ₓN top layer 102 (100 nm thick) is graded from approximately x=0.25 at the surface 114 to x=0.5 at the junction 105 between the two alloy layers. A p-type InₓGa₁₋ₓN bottom layer 104 (900 nm thick) is formed on the lower p-type side of the junction 105 that is graded from x=0.5 at the junction 105 to x=0.35 at the other side of the layer 104 at the junction with the electrical contact 108 that collects the current. The n-type and p-type doping were 10¹⁸ and 10¹⁷ cm⁻³, respectively, in this simulation. The band diagram in FIG. 7 illustrates some of the unique advantages offered by the InGaN and AlInN alloys which have a very wide range of direct band gap tuning. This contrasts with, for example, AlGaAs, for which the gap is direct for only some part of the alloying range. For the n-type top layer 102, the grading produces a built-in electric field which will transport minority carriers (holes) to the junction 105. Similarly, the grading (in the opposite direction, from high x to low x) on the p-type side of the junction 105 produces an electric field which will transport minority carriers (electrons) to the junction 105. The overall effect is a reduction in the recombination of minority carriers, where such recombination is an efficiency loss in solar cells. In the design in this embodiment, the n-type layer is made to be thin, so that it serves primarily as a collector of electrons from the p-type side. The grading on the p-type side is unique as compared to conventional thinking in that it goes from a lower band gap to a higher band gap. This will concentrate charge generation near the interface or junction 105, which could provide significant advantages depending on the properties of the materials used to make the device in practice. In general, there is an interplay between the charge generation rates for the different wavelengths of solar photons and the magnitude of the built-in electric field which can be optimized using the wide band gap tuning range available in InₓGa₁₋ₓN (and InₓAl₁₋ₓ-N).

In accordance with one or more embodiments, a compositionally graded Group III-nitride alloy can further be utilized in a multijunction tandem solar cell in which one of the solar cells includes a compositionally graded Group III-nitride alloy. A multijunction tandem solar cell includes a plurality (e.g., two, three, four, etc.) of P-N junction solar cells connected in series in a stacked arrangement. One representative example of a multijunction tandem solar cell that utilizes a Group III-nitride alloy in at least one of its solar cells is described in U.S. Pat. No. 7,217,882 issued on May 15, 2007 to Walukiewicz et al. and entitled, “BROAD SPECTRUM SOLAR CELL,” the contents of which are incorporated herein by reference. In such a multijunction tandem solar cell 200, as illustrated in FIG. 8 in accordance with one or more embodiments, any or all of the n-type and p-type regions of the subcells 202 can be compositionally graded in accordance with the compositionally graded Group III-nitride alloys described herein. In accordance with one or more embodiments, the barrier for the electrons at the interface 204 between the subcells 202 can be lowered by additional doping.

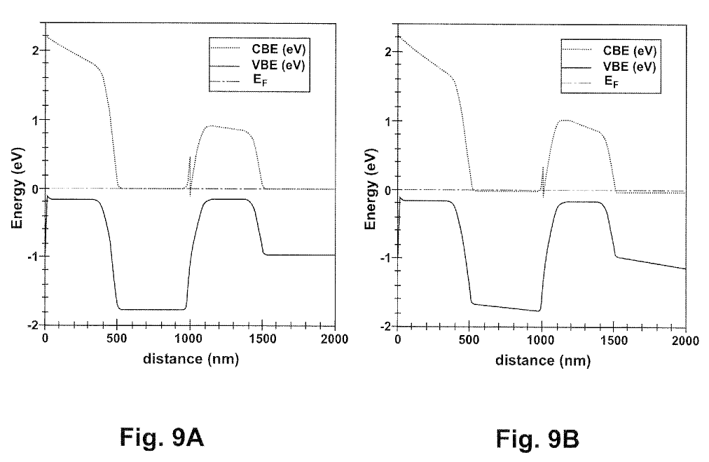

Referring to FIG. 9A, a band diagram for one specific example of an InGaN tandem solar cell having the structure of FIG. 7 with compositional grading is illustrated. In this example, the p-InGaN doping is 1×10¹⁷ cm⁻³ Mg (100 meV activation energy) and the n-InGaN doping is 1×10¹⁷ cm⁻³ (resonant donor). The InₓGa₁₋ₓN layers in the subcells are compositionally graded as follows: x=0.25 to 0.45 from 0-500 nm (upper p-type region); x=0.45 (constant) from 500-1000 nm (upper n-type region); x=0.75 to 0.85 from 1000-1500 nm (lower p-type region); x=0.85 (constant) from 1500-2000 nm (lower n-type region).

Referring to FIG. 9B, a band diagram for another specific example of an InGaN tandem solar cell having the structure of FIG. 7 with compositional grading is illustrated. In this example, the p-InGaN doping is 1×10¹⁷ cm⁻³ Mg (100 meV activation energy) and the n-InGaN doping is 1×10¹⁷ cm⁻³ (resonant donor). The InₓGa₁₋ₓN layers in the subcells are compositionally graded as follows: x=0.25 to 0.5 from 0-500 nm (upper p-type region); x=0.5 to 0.45 from 500-1000 nm (upper n-type region); x=0.65 to 0.85 from 1000-1500 nm (lower p-type region); x=0.85 to 0.75 from 1500-2000 nm (lower n-type region).

In accordance with one or more embodiments, a tandem solar cell is provided having a low-resistance tunnel junction formed between two solar cells in which one of the solar cells includes a compositionally graded Group III-nitride alloy. One representative example of such a low-resistance tunnel junction in an InGaN/Si tandem solar cell is described in PCT Patent Application Publication No. WO/2008/124160, published on Oct. 16, 2008 entitled, “LOW RESISTANCE TUNNEL JUNCTIONS FOR HIGH EFFICIENCY TANDEM SOLAR CELLS,” the contents of which are incorporated herein by reference. In such a tandem solar cell, in accordance with one or more embodiments, either or both of the n-type and p-type regions can be compositionally graded in accordance with the compositionally graded Group III-nitride alloys described herein, such that the grading can be linear or formed in according to another spatial function. In accordance with one or more embodiments, a back surface field can be used in the Si layer to improve charge collection.

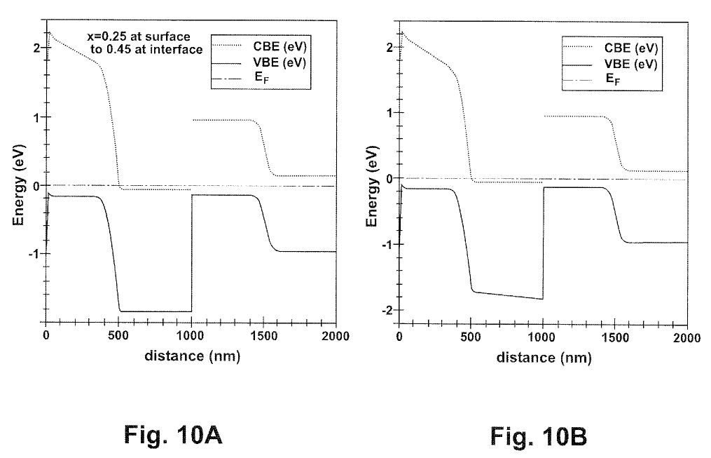

Referring to FIG. 10A, a band diagram for one specific example of an InGaN/Si tandem solar cell formed with compositional grading and having a low-resistance tunnel junction is illustrated. In this illustrated example, the band diagram was obtained by solving the Poisson equation numerically, the p-InGaN doping is 1×10¹⁷ cm⁻³ Mg (100 meV activation energy), and the n-InGaN doping is 1×10¹⁷ cm⁻³ (resonant donor). In the Si layer, p-type and n-type regions are 1×10¹⁷ (shallow donor/acceptor). The InₓGa₁₋ₓN layers in the subcells are compositionally graded as follows: x=0.25 to 0.45 in the p-type region, from 0-500 nm, providing an additional electric field to move the minority carriers (electrons) towards the n-type region (500-1000 nm).

Referring to FIG. 10B, a band diagram for another specific example of an InGaN/Si tandem solar cell formed with compositional grading and having a low-resistance tunnel junction is illustrated. In this illustrated example, the band diagram was obtained by solving the Poisson equation numerically, the p-InGaN doping is 1×10¹⁷ cm⁻³ Mg (100 meV activation energy), and the n-InGaN doping is 1×10¹⁷ cm⁻³ (resonant donor). In the Si layer, p-type and n-type regions are 1×10¹⁷ (shallow donor/acceptor). The InₓGa₁₋ₓN layers in the subcells are compositionally graded as follows: x=0.25 to 0.5 in the p-type region (0-500 nm) and x=0.5 to 0.55 in the n-type region (500-1000 nm). The grading in the n-type region creates an electric field that sends holes (minority carriers) to the p-type region.

1. A solar cell, comprising:
a layer of a compositionally graded Group III-nitride alloy;
a layer of photovoltaic material;
a single p-n junction between the compositionally graded Group III-nitride alloy layer and the photovoltaic layer; and
a plurality of depletion regions for charge separation associated with the single p-n junction.

2. The solar cell of claim 1, wherein the Group III-nitride alloy layer comprises InₓGa₁₋ₓN that is graded between two portions of the Group III-nitride alloy layer between two values of x, where 0.0≦x≦1.0.

3. The solar cell of claim 2, wherein the Group III-nitride alloy layer comprises InₓGa₁₋ₓN, where 0.25≦x≦0.45.

4. The solar cell of claim 1, wherein the Group III-nitride alloy layer comprises InₓAl₁₋ₓN that is graded between two portions of the Group III-nitride alloy layer between two values of x, where 0.0≦x≦1.0.

5. The solar cell of claim 4, wherein the Group III-nitride alloy layer comprises InₓAl₁₋ₓN, where 0.6≦x≦0.8.

6. The solar cell of claim 1, wherein the photovoltaic material comprises a silicon material.

7. The solar cell of claim 1, wherein the photovoltaic material comprises a compositionally graded Group III-nitride alloy.

8. The solar cell of claim 1, further comprising:
a first electrical contact coupled to the Group III-nitride alloy layer;
a layer of n+material formed on the layer of photovoltaic material; and
a second electrical contact coupled to the layer of n+material.

9. A solar cell, comprising:
a first junction of a Group III-nitride alloy having a first bandgap; and
a second junction of a Group III-nitride alloy having a second bandgap electrically coupled to the first junction,
wherein at least one of the first and second junctions includes a compositionally graded Group III-nitride alloy.

10. A semiconductor structure, comprising:
a first photovoltaic cell comprising a first material; and
a second photovoltaic cell comprising a second material, the second photovoltaic cell connected in series to the first photovoltaic cell,
wherein at least one of the first material and the second material comprise a compositionally graded Group III-nitride alloy;
wherein a low resistance tunnel junction is formed between the first and second photovoltaic cells.

11. The semiconductor structure of claim 10, wherein the compositionally graded Group III-nitride alloy comprises InₓGa₁₋ₓN that is graded between two portions of the Group III-nitride alloy between two values of x, where 0.0≦x≦1.0.

12. The semiconductor structure of claim 11, wherein the Group III-nitride alloy layer comprises InₓGa₁₋ₓN, where 0.25≦x≦0.45.

13. The semiconductor structure of claim 10, wherein the compositionally graded Group III-nitride alloy comprises InₓAl₁₋ₓN that is graded between two portions of the Group III-nitride alloy between two values of x, where 0.0≦x≦1.0.

14. The semiconductor structure of claim 13, wherein the Group III-nitride alloy layer comprises InₓAl₁₋ₓN, where 0.6≦x≦0.8.

15. A photovoltaic layer for a solar cell comprising:
a layer of a compositionally graded Group III-nitride alloy.

16. The photovoltaic layer for a solar cell of claim 15, wherein the compositionally graded Group III-nitride alloy layer comprises InₓGa₁₋ₓN that is graded between two portions of the Group III-nitride alloy layer between two values of x, where 0.0≦x≦1.0.

17. The photovoltaic layer for a solar cell of claim 16, wherein the compositionally graded Group III-nitride alloy layer comprises InₓGa₁₋ₓN, where 0.25≦x≦0.45.

18. The photovoltaic layer for a solar cell of claim 15, wherein the compositionally graded Group III-nitride alloy layer comprises InₓAl₁₋ₓN that is graded between two portions of the Group III-nitride alloy layer between two values of x, where 0.0≦x≦1.0.

19. The photovoltaic layer for a solar cell of claim 18, wherein the compositionally graded Group III-nitride alloy layer comprises InₓAl₁₋ₓN, where 0.6≦x≦0.8.
